(19) United States
(12) Patent Application Publication
(10) Pub. No.: US 2026/0026397 A1
(43) Pub. Date: Jan. 22, 2026

(54) SILICON SYSTEM SUBSTRATE WITH VERTICAL BRIDGE CHIPLET

(71) Applicant: Zero ASIC Corporation, Lexington, MA (US)

(72) Inventors: Andreas Olofsson, Lexington, MA (US); Lizabeth Keser, San Diego, CA (US)

(21) Appl. No.: 18/775,118

(22) Filed: Jul. 17, 2024

(51) Int. Cl. H01L 25/18; H01L 23/00; H01L 23/48; H01L 23/538

(52) U.S. Cl. CPC H01L 25/18; H01L 23/481; H01L 23/5386; H01L 24/14; H01L 24/16; H01L 24/97; H01L 2224/14051; H01L 2224/16145; H01L 2224/16235; H01L 2224/97; H01L 2225/06513; H01L 2924/1431

(57) ABSTRACT

An integrated circuit product includes a vertical bridge chiplet that includes through silicon vias (TSVs) to provide power delivery or other system input/output signals to an integrated circuit device. The vertical bridge chiplet and functional chiplets are coupled to the integrated circuit device using vertical interconnect. In an embodiment, the vertical bridge chiplet uses double-sided interconnect to couple system I/O from a package or printed circuit board to the integrated circuit device and reduces or eliminates the need for the integrated circuit device to include TSVs. The vertical bridge chiplet is separately manufactured and may be included in a library of functional chiplets of a modular chiplet system for use with a set of prefabricated integrated circuit devices formed from a semiconductor substrate with a set of chiplet interfaces to serve a variety of system applications without requiring custom silicon devices.

### CROSS-REFERENCE TO RELATED APPLICATION(S)

This application is related to U.S. patent application Ser. No. 18/753,356, entitled “Integrated Circuit Die Stitching Using Jumper Die,” filed on Jun. 25, 2024, naming Andreas Olofsson and Lizabeth Keser as inventors, which application is hereby incorporated by reference.

This application is related to U.S. patent application Ser. No. 18/771,693, entitled “Modular Chiplet System,” filed on Jul. 12, 2024, naming Andreas Olofsson as inventor, which claims the benefit under 35 U.S.C. § 119 of U.S. Provisional Application No. 63/514,827, filed on Jul. 21, 2023, naming Andreas Olofsson as inventor, which applications are hereby incorporated by reference.

### BACKGROUND

### Field of the Invention

This invention relates to integrated circuit products and more particularly relates to interconnect of structures in integrated circuit products.

### Description of the Related Art

In general, chiplets are relatively small integrated circuit die that contain well-defined functionality and may be combined with other chiplets to form a larger, more complex Application-Specific Integrated Circuit (ASIC). The use of chiplets as building blocks to form a larger ASIC may reduce the cost of product development by reusing verified integrated circuit die but requires connecting separate integrated circuit die, which may include connecting stacked integrated circuit die. Conventional techniques for interconnecting integrated circuit die includes stacking integrated circuit die on an interposer and using interconnects formed by Back End of the Line processes (e.g., integrated circuit manufacturing processes that form conductive layers, insulating layers, and conductive vias therebetween). In general, through-silicon vias (TSVs) are vertical electrical connections that may be used to connect integrated circuit die stacked on top of an interposer. Forming TSVs is relatively expensive since it requires substantial processing time and complex processing. For example, TSVs are formed by etching trenches into a substrate and filling the trenches with insulating liners and conductive materials. Various known methods may be used to form TSVs including via-first, via-middle, and via-last construction. Those methods include dielectric deposition, metal deposition, electroplating, chemical mechanical planarization, and etch techniques. Via-first construction includes creating a relatively deep via in a substrate from the top of the substrate followed by a reveal process that exposes the TSVs at the back side of the substrate. The resulting vias can be a few microns in diameter and are relatively deep and have relatively high aspect ratios as compared to other features of an integrated circuit. The ability to form TSVs in a substrate may be available from a limited number of providers. In addition, since qualification of TSVs for high volume manufacturing using the newest process nodes typically lags availability of the newest process nodes for high volume manufacturing, the ability to form TSVs in a substrate may be available for a limited selection of process nodes.

Other techniques that might be used to interconnect integrated circuit die include silicon bridges, which use advanced packaging technology (e.g., fan-out) to route signals laterally using redistribution layers to interconnect (e.g., solder ball). Those techniques are incompatible with the substantial number of bridges required between chiplets, decrease yield, increase silicon cost, and have technical challenges that include managing warpage and die movement in fan-out. Multi-die interconnect silicon bridges that are embedded in a substrate are costly and have supply chain issues. Multi-die interconnect using silicon interposer technologies with TSVs are costly, reticle size limited, and have supply chain issues. Accordingly, improved techniques for connecting chiplets to form an integrated circuit product are desired.

### SUMMARY OF EMBODIMENTS OF THE INVENTION

In at least one embodiment of the invention, an integrated circuit product includes a semiconductor substrate having conductive routing coupled to a conductive interface structure on a first surface of the semiconductor substrate. The integrated circuit product includes a vertical bridge die stacked with the semiconductor substrate and vertically coupled to the conductive interface structures with respect to the first surface of the semiconductor substrate. The integrated circuit product includes at least one functional integrated circuit die stacked with the semiconductor substrate and coupled to a second conductive interface structure on the first surface of the semiconductor substrate. The at least one functional integrated circuit die is laterally adjacent to the vertical bridge die with respect to the first surface of the semiconductor substrate. The conductive routing may be included in a network-on-chip. The vertical bridge die and the at least one functional integrated circuit die are disposed in corresponding tiles of an N-by-M tile map of a surface of the semiconductor substrate. The vertical bridge die may be separated from the at least one functional integrated circuit die by a lane having a predetermined width, wherein N and M are integers of at least one. An additional vertical bridge die may be stacked with the semiconductor substrate. The at least one functional integrated circuit die may include a first functional integrated circuit die disposed between the vertical bridge die and the additional vertical bridge die. The additional vertical bridge die may be disposed in another corresponding tile of the N-by-M tile map of the surface of the semiconductor substrate and the additional vertical bridge die is separated from the at least one functional integrated circuit die by another lane having the predetermined width. The first surface of the semiconductor substrate and a back side of the at least one functional integrated circuit die may be facing a package substrate. The vertical bridge die may be between the first surface of the semiconductor substrate and the package substrate. The vertical bridge die may include a first die interface at a first surface of the vertical bridge die, a second die interface at a second surface of the vertical bridge die, and a vertical conductive structure coupled between the first die interface and the second die interface.

In at least one embodiment, a method for manufacturing a vertical bridge die includes forming through-silicon vias in a substrate, forming a first die interface on a front side of the substrate by patterning a conductive layer, and forming a second die interface on a back side of the substrate by forming vertical conductive structures coupled to the through-silicon vias. The first die interface is coupled to the through-silicon vias. The substrate may be an electrical insulator. The conductive layer may be a redistribution layer formed on the front side of the substrate with no intervening conductive layer. The vertical bridge die may include only passive conductive structures.

In at least one embodiment, a method of manufacturing an integrated circuit product includes vertically attaching a vertical bridge die to a first die interface of a semiconductor substrate including a conductive structure, vertically attaching at least one functional integrated circuit die to a second die interface of the semiconductor substrate, the second die interface being coupled to the first die interface by the conductive structure, and singulating a module from a remainder of the semiconductor substrate. The module includes the conductive structure, the vertical bridge die, and the at least one functional integrated circuit die. A first functional integrated circuit die of the at least one functional integrated circuit die is laterally adjacent to the vertical bridge die with respect to a first surface of the semiconductor substrate. The method may include attaching the module to a package substrate by vertically attaching the vertical bridge die to conductive structures on the package substrate. The vertical bridge die and the at least one functional integrated circuit die may be stacked between the semiconductor substrate and the package substrate. A back side of the at least one functional integrated circuit die and a front side of a first integrated circuit die of the semiconductor substrate face the package substrate. The method may include attaching the module to a printed circuit board by vertically attaching the vertical bridge die to conductive structures on the printed circuit board. The vertical bridge die and the at least one functional integrated circuit die are stacked between the semiconductor substrate and the printed circuit board. A back side of the at least one functional integrated circuit die and a front side of a first integrated circuit die of the semiconductor substrate face the printed circuit board.

The method of manufacturing an integrated circuit product may include attaching additional vertical bridge die stacked with the semiconductor substrate. The first functional integrated circuit die is laterally disposed between the vertical bridge die and the additional vertical bridge die. The vertical bridge die, the first functional integrated circuit die, and the additional vertical bridge die are disposed in corresponding tiles of an N-by-M tile map of a surface of the semiconductor substrate and the vertical bridge die is separated from the first functional integrated circuit die by a lane having a predetermined width, where N and M are integers of at least one. The method may include vertically attaching a jumper die to a first integrated circuit die of the semiconductor substrate and a second integrated circuit die of the semiconductor substrate. The first integrated circuit die may be separated from the second integrated circuit die by a scribe line of a first surface of the semiconductor substrate. The jumper die may span the scribe line, overlap a first portion of the first integrated circuit die, and overlap a second portion of the second integrated circuit die.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a functional block diagram of an exemplary integrated circuit product including a fabric device and I/O chiplets.

FIG. 2 illustrates a cross-sectional view of an exemplary packaged integrated circuit product.

FIG. 3 illustrates a cross-sectional view of an exemplary packaged integrated circuit product including a vertical bridge chiplet consistent with at least one embodiment of the invention.

FIG. 4 illustrates a cross-sectional view of an exemplary integrated circuit product including a vertical bridge chiplet coupled directly to a printed circuit board consistent with at least one embodiment of the invention.

FIG. 5 illustrates an exemplary process flow for manufacturing a vertical bridge chiplet consistent with at least one embodiment of the invention.

FIG. 6 illustrates an exemplary process flow for packaging an integrated circuit product including a vertical bridge chiplet consistent with at least one embodiment of the invention.

FIG. 7 illustrates an exemplary process flow for packaging an integrated circuit product including a vertical bridge chiplet without a package substrate consistent with at least one embodiment of the invention.

FIG. 8 illustrates a cross-sectional view of an exemplary integrated circuit product including a vertical bridge chiplet and a jumper chiplet consistent with at least one embodiment of the invention.

The use of the same reference symbols in different drawings indicates similar or identical items.

### DETAILED DESCRIPTION

An integrated circuit product includes a vertical bridge chiplet (i.e., vertical bridge die) that includes TSVs to provide power delivery or other system input/output signals to an integrated circuit device. The vertical bridge chiplet and functional chiplets (i.e., functional integrated circuit die) are coupled to the integrated circuit device using vertical interconnect. In general, vertical interconnect (e.g., conductive pillar, conductive bump, conductive microbump, hybrid bond, or other suitable conductive structure known the in art) is a conductive structure that couples in a vertical direction, i.e., orthogonally, with respect to a surface of a substrate. In an embodiment, the vertical bridge chiplet uses double-sided interconnect to couple system I/O from a package or printed circuit board to the integrated circuit device and reduces or eliminates the need for the integrated circuit device to include TSVs. The vertical bridge chiplet is separately manufactured and may be included in a library of functional chiplets of a modular chiplet system for use with a set of prefabricated integrated circuit devices formed from a semiconductor substrate (e.g., a small, medium, or large substrate of silicon, aluminum oxide, sapphire, germanium, gallium arsenide, an alloy of silicon and germanium, or indium phosphide) with a set (e.g., 4, 16, or 64) of chiplet interfaces to serve a variety of system applications without requiring custom silicon devices. In an embodiment, the library of functional chiplets includes at least one Central Processing Unit (CPU), Field Programmable Gate Array (FPGA), Digital Signal Processor (DSP), Neural Processing Unit (NPU), Intelligence or Infrastructure Processing Unit (IPU), Machine Learning (ML) processor, Graphics Processing Unit (GPU), Static Random Access Memory (SRAM), Double Data Rate Synchronous Dynamic Random-Access Memory (DDR SDRAM), input/output (I/O) manager, Serializer/Deserializer (SerDes), Analog-to-Digital Converters (ADCs), Digital-to-Analog Converters (DACs), Non-Volatile Memory (NVM), or other functional modules. In an embodiment, the integrated circuit device is a fabric device including a network-on-chip that provides services to and interconnects functional chiplets attached to the integrated circuit device.

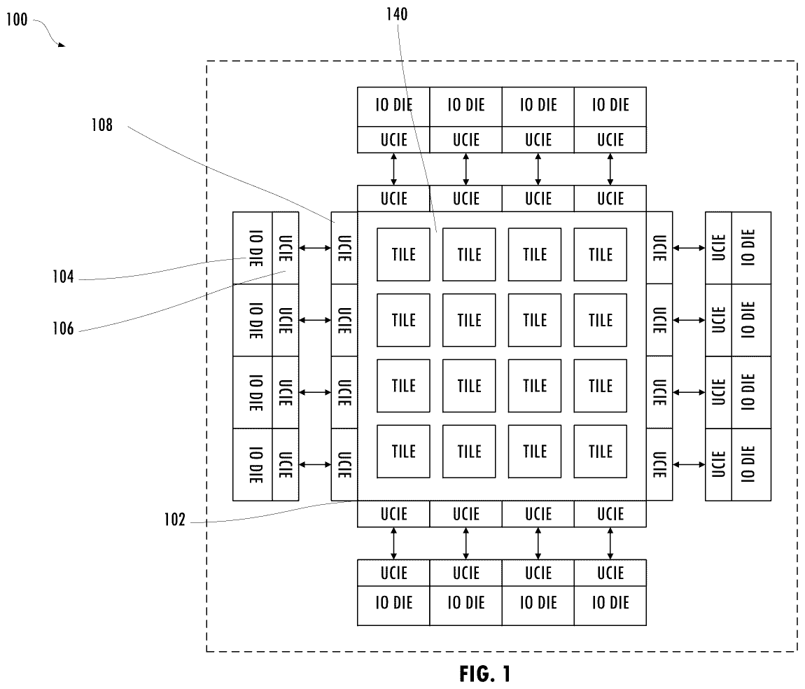

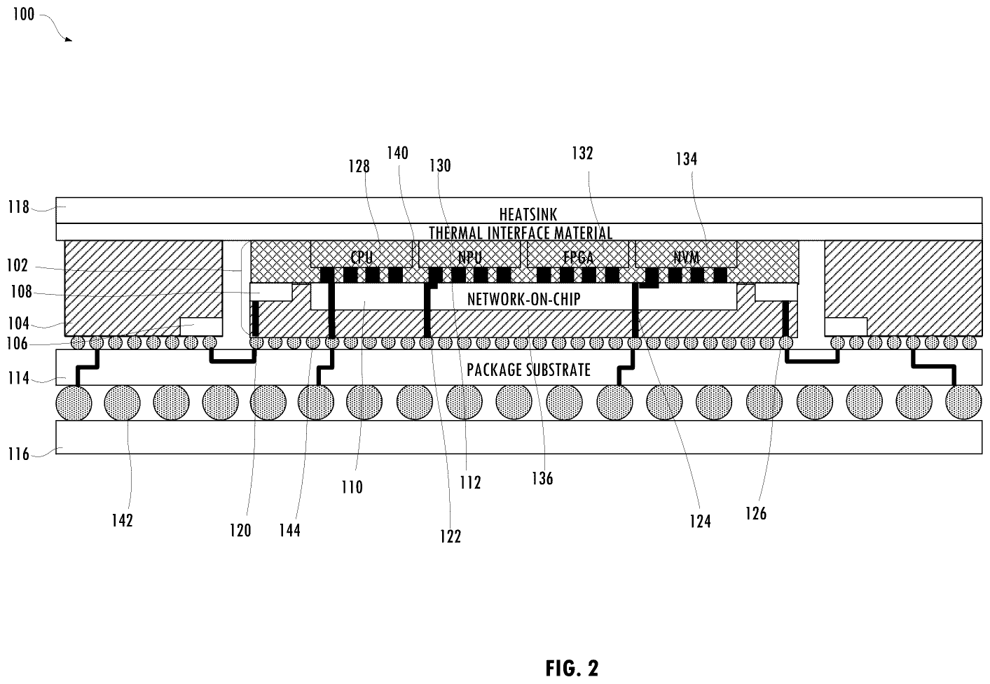

FIGS. 1 and 2 illustrate integrated circuit product 100 designed using an exemplary modular chiplet system. Integrated circuit product 100 includes fabric device 102 having TSVs 120, 122, 124, and 126 that couple system I/O between vertical conductors coupled to a package and chiplets 128, 130, 132, and 134 via network-on-chip 110. Fabric device 102 provides services (e.g., using network-on-chip 110) to chiplets 128, 130, 132, and 134. Integrated circuit product 100 includes vertical interfaces to couple network-on-chip 110 to chiplets stacked with fabric device 102. In addition, integrated circuit product 100 includes two-dimensional (2D) connections between a standard interface 108 of fabric device 102 to standard interface 106 of I/O chiplet 104 disposed laterally adjacent to fabric device 102 with respect to package substrate 114 (e.g., an organic or ceramic substrate).

In an embodiment, fabric device 102 includes a plurality of chiplet interfaces having a discrete size and pinout. Fabric device 102 includes one discrete chiplet interface per tile of predetermined size in a tile grid of a surface of semiconductor substrate 136 of fabric device 102. Embodiments of fabric device 102 include an N-by-M tile map (e.g., an N-by-M grid array) of discrete chiplet interfaces, where N and M are integers greater than or equal to one. Although the tile map is described as a rectangular array of discrete chiplet interfaces, other embodiments use different geometric patterns (e.g. cross, rhombus, parallelogram, triangular, or irregular shapes). Each chiplet interface of the fabric device is separated from an adjacent chiplet interface by a lane (e.g., lane 140) having a predetermined width. For example, fabric device 102 of FIG. 1 includes a 4×4 grid of discrete chiplet interfaces. Each chiplet interface includes at least pads for 3D attachment to a corresponding interface of a chiplet. In some embodiments, a discrete chiplet interface is compliant with a predetermined wafer-to-die or die-to-die interconnection specification (e.g., Universal Chiplet Interconnect Express (UCIe), The Bunch of Wires (BoW), Advanced Interface Bus (AIB), Open High Bandwidth Interface (HBI), Optical Internetworking Forum (OIF) Extra Short Reach (XSR), or other suitable wafer-to-die or die-to-die interconnection specification).

The exemplary 4×4 tile map of chiplet interfaces receives three-dimensional (3D) connections to chiplets 112 that are stacked with fabric device 102. Sixteen standard interfaces 108 (e.g., UCIe interfaces) are coupled to 2D connections to standard interfaces 106 of I/O chiplets 104 disposed laterally adjacent to fabric device 102 with respect to package substrate 114. Semiconductor substrate 136 of fabric device 102 includes network-on-chip 110, which in an embodiment includes 16 MB of distributed SRAM, 64 in-order RISC-V CPU management cores and chiplet interfaces for connecting to chiplets stacked with fabric device 102. Fabric device 102 includes power delivery networks, clocking, system management, and general-purpose I/O. Package substrate 114 provides system I/O between printed circuit board 116 and fabric device 102 and I/O chiplets 104 via vertical conductive structures 142 (e.g., conductive bumps) and vertical conductive structures 144 (e.g., microbumps). The back side of the fabric device 102 and the front side of chiplets 112 are facing package substrate 114 and the front side of fabric device 102 (i.e., the side of fabric device 102 used to form network-on-chip 110) and the back side of chiplets 112 are facing heatsink 118.

In an embodiment, chiplets 112 are selected from a library of mechanically and electrically interchangeable, rotationally symmetrical chiplets that can be connected to fabric device 102 at an interface of at least one tile of the array of N×M tiles. The rotational symmetry of the interface enables a chiplet to be placed at any side of fabric device 102. In an embodiment, the modular chiplet system implements a shared memory architecture that allows chiplets to communicate with each other using read/write transactions that are routed by network-on-chip 110. Network-on-chip 110 also enables communication between different resources of fabric device 102. In some embodiments, bidirectional, low-latency 3D interfaces connect chiplets to network-on-chip 110. The bidirectional link serializes memory access transactions across the 3D interface. The bidirectional link can be source synchronous or include clock data recovery. In some embodiments, a parallel source synchronous data bus is used to improve energy efficiency. A chiplet-based system-in-package designed using the modular chiplet system is programmable using memory-mapped addressing.

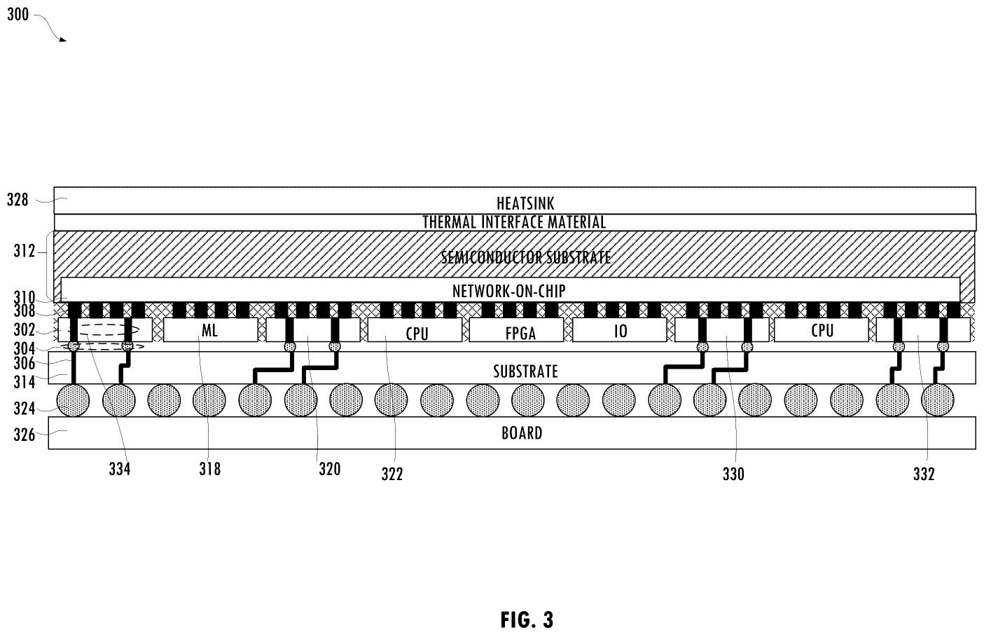

Referring to FIG. 3, integrated circuit product 300 includes fabric device 312, which implements network-on-chip 310. Unlike the integrated circuit product described above, integrated circuit product 300 does not include any TSVs. Instead, vertical bridge chiplets 302, 320, 330, and 332 provide system I/O to network-on-chip 310 of fabric device 312. In an embodiment, the system I/O provided by the vertical bridge chiplets include power supply signals (e.g., VDD and VSS) and in some embodiments, vertical bridge chiplets include vertical interconnect for other system I/O, e.g., data, clock, and other control signals. The TSVs may vary according to the type of signal being communicated. For example, TSVs in vertical bridge chiplets use different materials, dimensions, or densities for power supply signals as compared to materials, dimensions, or densities for high frequency data signals. Vertical interconnect 308 on a first side of vertical bridge chiplet 302 couples passive vertical interconnect 334 (e.g., TSVs) of vertical bridge chiplet 302 to an integrated circuit die interface of fabric device 312. Vertical interconnect 304 on a second side of vertical bridge chiplet 302 couples passive vertical interconnect 334 through vertical bridge chiplet 302 to conductive via 306 of package substrate 314, which interfaces to printed circuit board 326 using conductive bumps 324. The back side of fabric device 312 and the front side of chiplets 318 and 322 are facing heatsink 328 and the front side of fabric device 312 and the back side of chiplets 318 and 322 are facing a front side of package substrate 314, which includes conductive bumps 324 on its back side.

In at least one embodiment, limits on current delivery affect performance of a conventional ASIC. Accordingly, a plurality of vertical bridge chiplets are distributed across the semiconductor substrate of fabric device 312 to provide power supply current at various portions of fabric device 312. For example, VDD and VSS are provided by vertical bridge chiplets at a plurality of locations including the periphery of fabric device 312 and at interior locations of the N×M array of tiles. In at least one embodiment, vertical bridge chiplets are distributed throughout an integrated circuit module to provide data, clock, other control signals, or combinations thereof at locations corresponding to different parts of a package or printed circuit board footprint to improve system performance (e.g., reduce the impact of electromagnetic interference and attenuation). For example, vertical bridge chiplets are distributed proximate to circuitry of fabric device 312 to reduce the length of transmission lines and improve data signal performance. Vertical bridge chiplets 302 and 332 provide system I/O signals from package substrate 314 to fabric device 312 at the periphery of fabric device 312 and vertical bridge chiplets 320 and 330 provide system I/O signals from package substrate 314 to fabric device 312 at interior locations of fabric device 312. Although integrated circuit products are described herein including a fabric device consistent with a modular chiplet system, techniques described herein are applicable to other integrated circuit products.

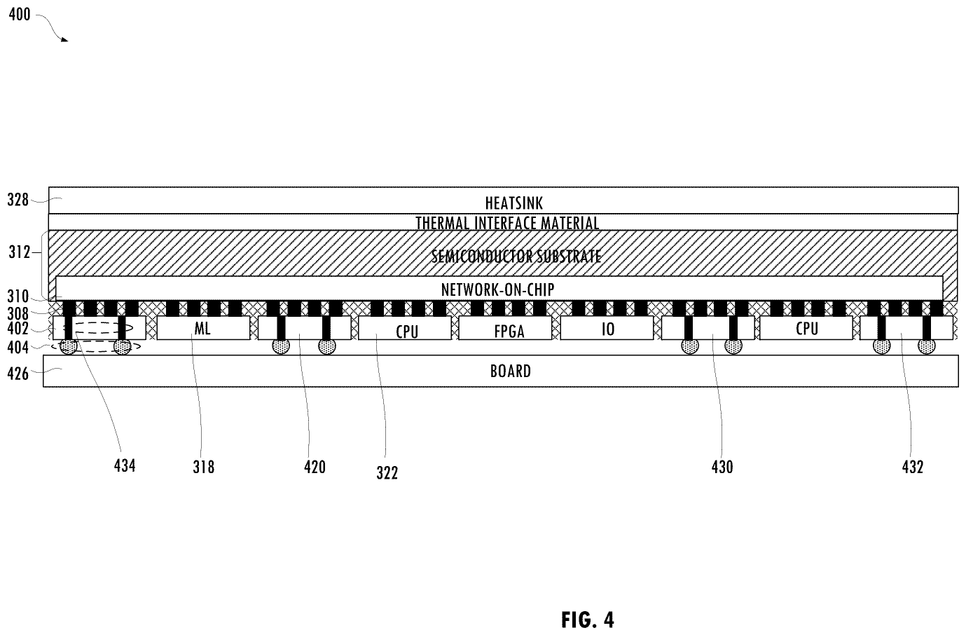

Referring to FIGS. 3 and 4, in at least one embodiment, integrated circuit product 400 includes vertical bridge chiplets 402, 420, 430, and 432 that include TSVs coupling first sides of the vertical bridge chiplets to the second sides of the vertical bridge chiplets and have vertical interconnect on the second sides that eliminate the need for a package substrate between an integrated circuit module and printed circuit board 326 of integrated circuit product 400. In general, printed circuit boards do not have fine routability (i.e., do not have fine conductor trace widths and spaces or fine via sizes) of substrates and features included in a printed circuit board are coarser than features that are manufactured by integrated circuit manufacturing techniques. Therefore, the vertical interconnect on the second sides of vertical bridge chiplets have characteristics sufficient for coupling the TSVs of vertical bridge chiplets 402, 420, 430, and 432 directly to printed circuit board 326, thereby eliminating the need for a package substrate 314 between a module including fabric device 312 and printed circuit board 326. In relatively small integrated circuit product embodiments (e.g., integrated circuit products including integrated circuit die having an area of less than 10 mm×10 mm), the density of system I/O is low enough to allow for larger vertical interconnect to be coupled directly to a vertical bridge chiplet. Accordingly, vertical interconnect 404 (e.g., larger conductive bumps) is larger than and has a wider pitch than vertical interconnect 304 (e.g., smaller conductive bumps) and vertical interconnect 404, provide board-level reliability and robust solder joint and therefore can be directly coupled to printed circuit board 326 without including an intervening package substrate. TSVs of vertical bridge chiplets in embodiments of integrated circuit product 400 may have the same diameter and pitch as TSVs of vertical bridge chiplets in embodiments of integrated circuit product 300, but the TSVs of vertical bridge chiplets in those embodiments of integrated circuit product 400 include additional TSVs ganged together to connect to vertical interconnect. For example, an embodiment of integrated circuit product 300 includes passive vertical interconnect 334 having one TSV coupled to each conductive bump of vertical interconnect 304 or multiple TSVs ganged together and coupled to a corresponding conductive bump of vertical interconnect 304. In an embodiment that is similar to that embodiment of integrated circuit product 300 but eliminates the need for package substrate 314, integrated circuit product 400 includes a greater number of TSVs ganged together in each passive vertical interconnect 434 to connect to a corresponding conductive bump of vertical interconnect 404. In some embodiments of integrated circuit product 400 that attach a larger integrated circuit die (e.g., integrated circuit die having an area of greater than 10 mm×10 mm) directly to printed circuit board 426, printed circuit board 426 has material properties that provide suitable assembly yield and reliability. By eliminating the need for the package substrate, vertical bridge chiplets reduce the cost of an associated integrated circuit product and may improve system performance as compared to embodiments using a package substrate.

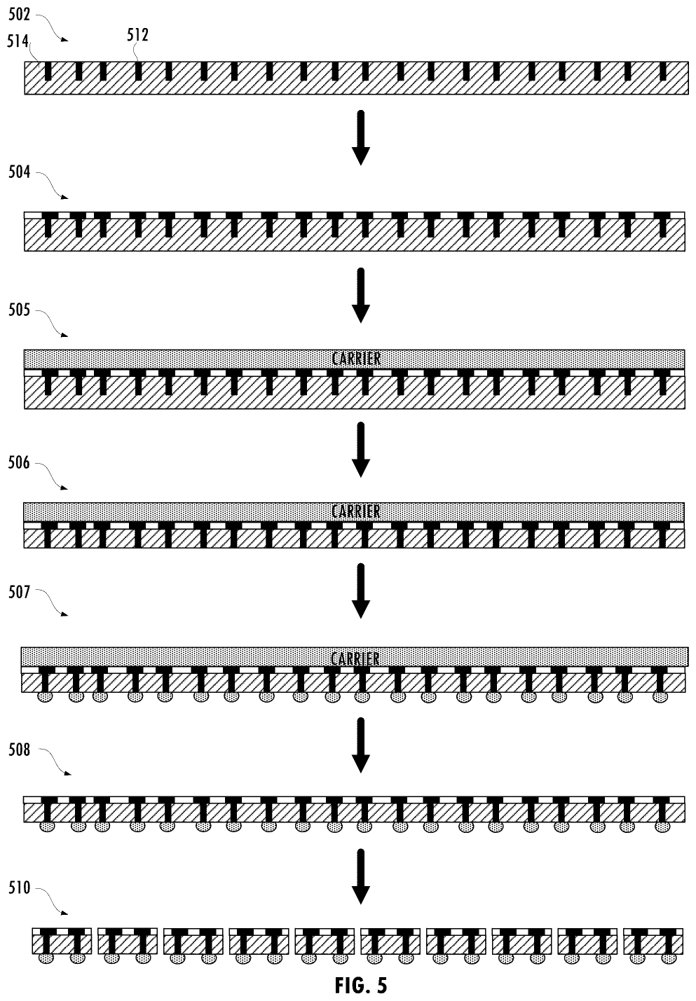

Referring to FIG. 5, an exemplary process flow for manufacturing a vertical bridge chiplet includes forming TSVs in a substrate, e.g., by etching trenches into a substrate and filling the trenches with insulating liners and conductive materials using known methods for forming TSVs (502). Those methods may include dielectric deposition, metal deposition, electroplating, chemical mechanical planarization, etch techniques, or other known integrated circuit manufacturing techniques. Via-first construction includes creating a deep via in the substrate from a top surface (i.e., front side) followed by a reveal process that exposes the TSVs at a bottom surface (i.e., back side). The resulting vias can be a few microns in diameter and are relatively deep and have high aspect ratios as compared to integrated circuit features. In an embodiment, substrate 514 is a semiconductor substrate although other embodiments of a vertical bridge chiplet that include no active circuits (i.e., no diodes or transistors) use glass or other electrically insulating material as the substrate for the vertical bridge chiplet.

Next, a first side of the substrate (e.g., the top surface or front side having TSVs at the surface) is patterned using a conductive layer (e.g., a redistribution layer or other conductive layer) (504). In a conventional integrated circuit manufacturing process, a redistribution layer is any layer formed on the integrated circuit used to route electrical connections between contact pads on an integrated circuit die and a location of a package contact. Forming a redistribution layer may include depositing and patterning conductive layers to transform an existing input/output layout into a pattern that satisfies the requirements of a solder bump design. A redistribution layer is typically formed above a passivation layer, i.e., a layer formed on an integrated circuit to provide electrical stability by protecting the integrated circuit from moisture, contamination particles, and mechanical damage. The passivation layer may include silicon dioxide, silicon nitride, polyimide, or other suitable passivation materials. Redistribution layers typically have thicknesses substantially greater than the thicknesses of typical dielectric and conductive layers formed on an integrated circuit die. For example, a typical conductive layer in an integrated circuit is less than 1 μm thick and corresponding dielectric layers are also less than 1 μm thick. However, conductive layers in an exemplary redistribution layer are at least 2 μm thick and corresponding dielectric layers are at least 5 μm thick. In another embodiment, the dielectric layers are at least 15 μm thick. Redistribution dielectric layers may include silicon nitride, oxynitride, silicon oxide, benzocyclobutene (BCB), polyimide, or other suitable materials. Redistribution conductive layers may include aluminum, copper, or other suitable materials. In at least one embodiment of a vertical bridge chiplet, the redistribution layer is the only conductive layer formed on the substrate and is in direct contact with the TSVs. Although the vertical bridge chiplet is being described as having conductive pads formed using redistribution layers, in other embodiments, other conductive and dielectric layers may be used. In other embodiments, rather than forming the conductive pads, vertical conductive structures are formed in direct contact with the TSVs.

After forming conductive pads coupled to the TSVs, a carrier substrate is attached to the substrate (e.g., using thermal release tape) for further processing of the vertical bridge chiplet (505). In an embodiment, the further processing includes TSV reveal steps to expose the TSVs at the back side of the substrate (506). After revealing the TSVs, vertical conductive structures (e.g., conductive bumps) are formed in contact with the revealed TSVs (507). After forming vertical conductive structures, the carrier is removed (508) and vertical bridge chiplets are singulated from the remainder of the substrate (e.g., using a wafer saw or other scribing, breaking, sawing, cutting or dicing technique to separate a finished wafer into individual vertical bridge chiplets) (510).

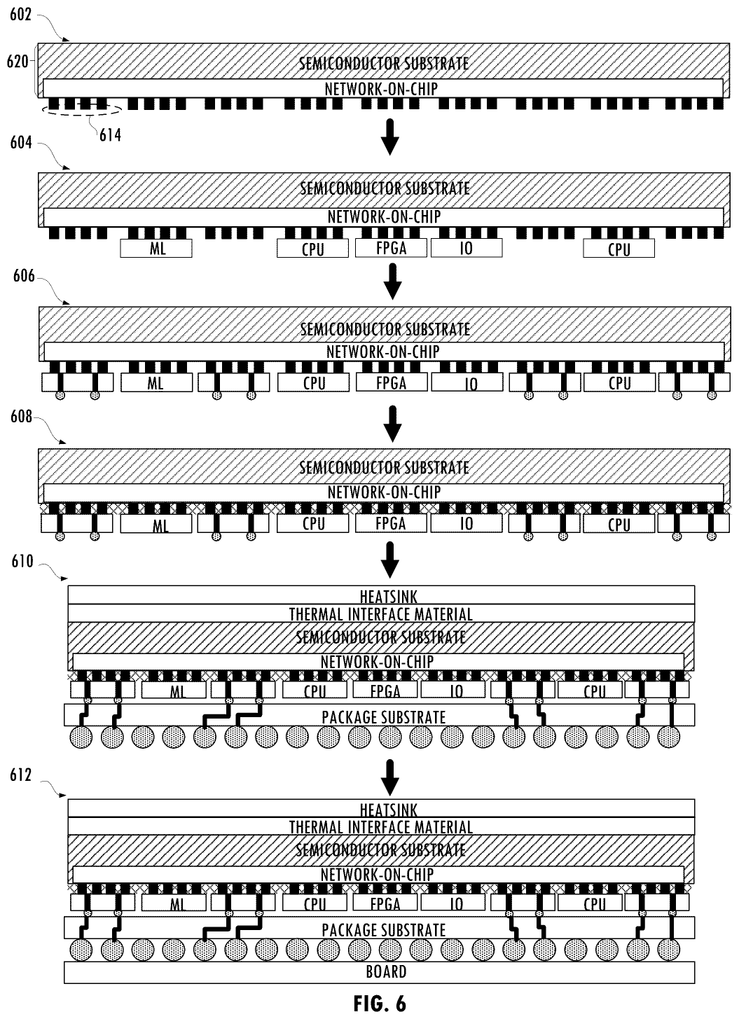

A fabric device or other integrated circuit device is manufactured using a semiconductor substrate according to a separate process flow of FIG. 6. In an embodiment, vertical interconnect 614 (e.g., conductive bumps) are formed on fabric device 620 at suitable locations for chiplets to be attached according to a target application (602). Forming the vertical interconnect on the fabric device simplifies, and reduces the cost of, manufacturing vertical bridge chiplets, which otherwise would require forming vertical interconnect coupled to TSVs 512 or redistribution layer contacts formed in step 504 of FIG. 5. Referring back to FIG. 6, after vertical interconnect 614 are formed on fabric device 620, assembly of an integrated circuit module includes attaching at least one functional chiplet (604). In an embodiment, vertical bridge chiplets are attached after attaching the functional chiplet(s) (606). However, in other embodiments, all chiplets are attached at the same time or vertical bridge chiplets are attached prior to attaching functional chiplets. The melting temperature of the solder used for each type of chiplet and solder reflow process may vary according to the order of attaching the various chiplets.

After the chiplets are attached to fabric device 620, underfill is applied between fabric device 620 and the chiplets and between the various chiplets to mechanically stabilize the chiplets and vertical interconnect (608). A module including fabric device 620 and the encapsulated chiplets is singulated before thermal interface material and any heatsink are attached to a back side of fabric device 620 and before the vertical bridge chiplets are attached to a package substrate (610). The package substrate is then attached to a printed circuit board (e.g., using surface mount technology or other attachments techniques known in the art) (612).

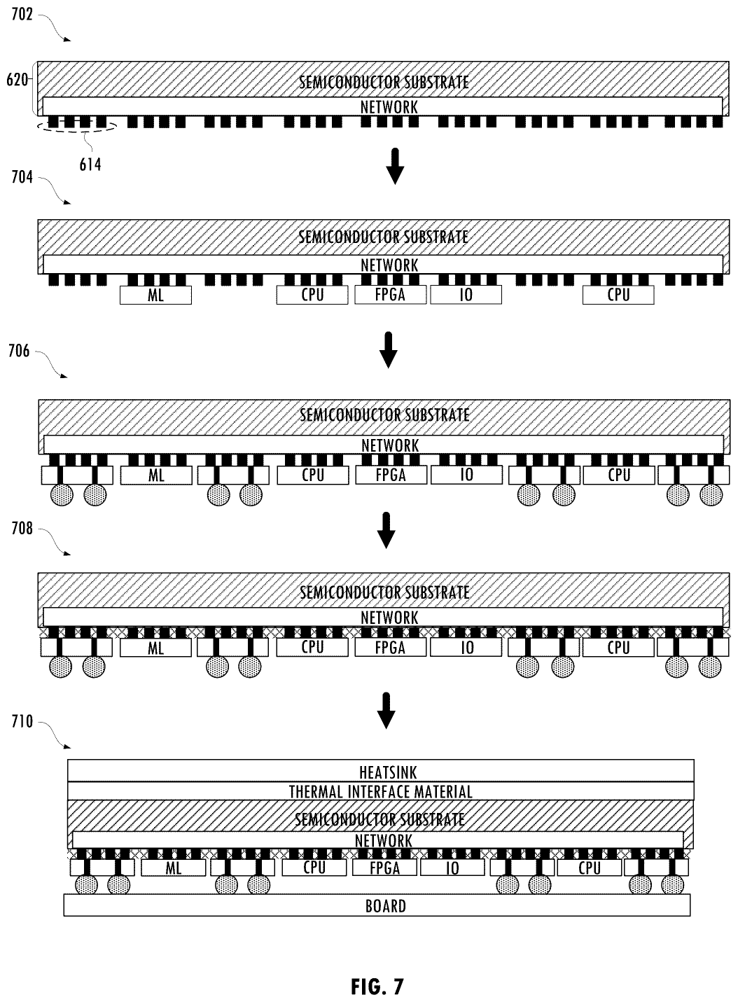

Referring to FIG. 7, in an embodiment, vertical bridge chiplets having a suitable size and pitch for eliminating a package substrate and connecting directly to a printed circuit board are used. Vertical interconnect 614 are formed on the fabric device (702). Then, assembly of an integrated circuit module includes attaching at least one functional chiplet (704). In an embodiment, vertical bridge chiplets are attached after attaching functional chiplet(s) (706). However, in other embodiments, all chiplets are attached at the same time or vertical bridge chiplets are attached prior to attaching functional chiplets. After all chiplets are attached to a fabric device, underfill is applied between the fabric device and the chiplets and between the various chiplets to mechanically stabilize the chiplets and vertical interconnect (708). A module including fabric device 620 and encapsulated chiplets is singulated before thermal interface material and any heatsink are attached to a back side of the fabric device. After applying underfill between fabric device 620 and the chiplets and between the various chiplets to mechanically stabilize the chiplets and vertical interconnect (708), a module including fabric device 620 and encapsulated chiplets is singulated before thermal interface material and any heatsink are attached to a back side of the fabric device. Then, the vertical bridge chiplets are attached directly to a printed circuit board (710).

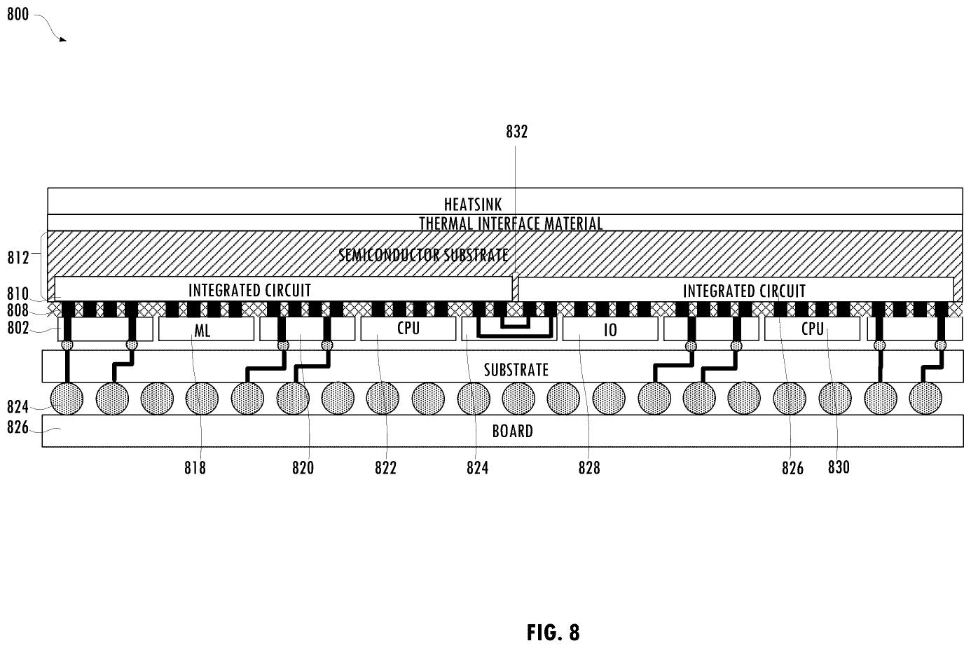

In an embodiment, the functional chiplets include a jumper chiplet, which may include functional circuitry in addition to conductive structures. Referring to FIG. 8, in at least one embodiment, fabric device 812 includes an integrated circuit design that exceeds a reticle limit of the manufacturing technology used to manufacture fabric device 812 and the integrated circuit design is formed by at least integrated circuit die 810 and integrated circuit die 826. Accordingly, in addition to functional chiplets 818, 822, 828 and 830, and vertical bridge chiplet 802 and 820, integrated circuit product 800 includes jumper chiplet 824, which includes conductive structures and may include other functionality (e.g., CPU, NPU, FPGA, or NVM). Jumper chiplet 824 spans scribe line 832 between integrated circuit die 810 and integrated circuit die 826. A first portion of jumper chiplet 824 is stacked with a first portion of integrated circuit die 810, and a second portion of jumper chiplet 824 is stacked with a first portion of integrated circuit die 826. The conductive structure in jumper chiplet 824 communicatively couples integrated circuit die 810 to integrated circuit die 826.

Thus, techniques for reducing or eliminating TSVs from an integrated circuit die or interposer have been described. The techniques include a vertical bridge chiplet that provides vertical interconnection for system I/O between an integrated circuit die and a package or printed circuit board. Eliminating TSVs from the integrated circuit die or interposer reduces manufacturing complexity and may allow use of newest processing technology nodes that have not yet qualified a TSV structure, or use of other manufacturing processes that do not offer TSV structures. Furthermore, since a vertical bridge chiplet is smaller size than an interposer, embodiments of an integrated circuit product using a vertical bridge chiplet solution is less expensive than embodiments of the integrated circuit product using an interposer solution. In addition, use of a vertical bridge chiplet may eliminate the need for a package substrate from some embodiments of an integrated circuit product. The vertical bridge chiplet may be processed using different technology than other integrated circuits of an integrated circuit product. The vertical bridge chiplet may be included in a library of chiplets for use by a modular chiplet system in design of various integrated circuit products.

The description of the invention set forth herein is illustrative and is not intended to limit the scope of the invention as set forth in the following claims. For example, while the invention has been described in an embodiment in which an integrated circuit product includes a fabric device, one of skill in the art will appreciate that the teachings herein can be utilized with other integrated circuit die stacked with chiplets or other integrated circuit die. The terms “first,” “second,” “third,” and so forth, as used in the claims, unless otherwise clear by context, are to distinguish between different items in the claims and do not otherwise indicate or imply any order in time, location or quality. For example, “a first received signal” and “a second received signal,” do not indicate or imply that the first received signal occurs in time before the second received signal. Variations and modifications of the embodiments disclosed herein may be made based on the description set forth herein, without departing from the scope of the invention as set forth in the following claims.

What is claimed is:

1. An integrated circuit product comprising:
a semiconductor substrate including conductive routing coupled to a conductive interface structure on a first surface of the semiconductor substrate;
a vertical bridge die stacked with the semiconductor substrate and vertically coupled to the conductive interface structure with respect to the first surface of the semiconductor substrate; and
at least one functional integrated circuit die stacked with the semiconductor substrate and coupled to a second conductive interface structure on the first surface of the semiconductor substrate, the at least one functional integrated circuit die being laterally adjacent to the vertical bridge die with respect to the first surface of the semiconductor substrate.

2. The integrated circuit product as recited in claim 1 further comprising:
wherein the conductive routing is included in a network-on-chip, the vertical bridge die and the at least one functional integrated circuit die are disposed in corresponding tiles of an N-by-M tile map of a surface of the semiconductor substrate and the vertical bridge die is separated from the at least one functional integrated circuit die by a lane having a predetermined width, wherein N and M are integers of at least one.

3. The integrated circuit product as recited in claim 2 further comprising:
additional vertical bridge die stacked with the semiconductor substrate, the at least one functional integrated circuit die including a first functional integrated circuit die disposed between the vertical bridge die and the additional vertical bridge die,
wherein the additional vertical bridge die is disposed in another corresponding tile of the N-by-M tile map of the surface of the semiconductor substrate and the additional vertical bridge die is separated from the at least one functional integrated circuit die by another lane having the predetermined width.

4. The integrated circuit product as recited in claim 2 wherein the vertical bridge die communicates system input/output signals between a package substrate and the at least one functional integrated circuit die via the network-on-chip of the semiconductor substrate and the conductive interface structure.

5. The integrated circuit product as recited in claim 2 wherein the first surface of the semiconductor substrate and a back side of the at least one functional integrated circuit die are facing a package substrate, the vertical bridge die is between the first surface of the semiconductor substrate and the package substrate.

6. The integrated circuit product as recited in claim 1 wherein the vertical bridge die comprises:
a first die interface at a first surface of the vertical bridge die;
a second die interface at a second surface of the vertical bridge die; and
a vertical conductive structure coupled between the first die interface and the second die interface.

7. The integrated circuit product as recited in claim 6,
wherein the vertical conductive structure is passive interconnect formed from a through-silicon via and the vertical bridge die includes only passive structures, and
wherein the semiconductor substrate does not include through-silicon vias.

8. The integrated circuit product as recited in claim 1 wherein the vertical bridge die has a rotationally symmetric pinout.

9. A method for manufacturing a vertical bridge die comprising:
forming through-silicon vias in a substrate;
forming a first die interface on a front side of the substrate by patterning a conductive layer, the first die interface being coupled to the through-silicon vias; and
forming a second die interface on a back side of the substrate by forming vertical conductive structures coupled to the through-silicon vias.

10. The method as recited in claim 9 wherein the substrate is an electrical insulator.

11. The method as recited in claim 9 wherein the conductive layer is a redistribution layer formed on the front side of the substrate with no intervening conductive layer.

12. The method as recited in claim 9 further comprising:
attaching a carrier substrate to the conductive layer before forming the second die interface;
revealing the through-silicon vias on the back side of the substrate;
forming the vertical conductive structures coupled to the through-silicon vias on the back side of the substrate;
removing the carrier substrate; and
singulating the vertical bridge die from the substrate.

13. The method as recited in claim 9 wherein the vertical bridge die includes only passive conductive structures.

14. The vertical bridge die formed by the method as recited in claim 9.

15. A method of manufacturing an integrated circuit product, the method comprising:
vertically attaching a vertical bridge die to a first die interface of a semiconductor substrate including a conductive structure;
vertically attaching at least one functional integrated circuit die to a second die interface of the semiconductor substrate, the second die interface being coupled to the first die interface by the conductive structure; and
singulating a module from a remainder of the semiconductor substrate, the module including the conductive structure, the vertical bridge die, and the at least one functional integrated circuit die,
wherein a first functional integrated circuit die of the at least one functional integrated circuit die is laterally adjacent to the vertical bridge die with respect to a first surface of the semiconductor substrate.

16. The method as recited in claim 15 further comprising:
attaching the module to a package substrate by vertically attaching the vertical bridge die to conductive structures on the package substrate, the vertical bridge die and the at least one functional integrated circuit die being stacked between the semiconductor substrate and the package substrate,
wherein a back side of the at least one functional integrated circuit die and a front side of a first integrated circuit die of the semiconductor substrate face the package substrate.

17. The method as recited in claim 15 further comprising:
attaching the module to a printed circuit board by vertically attaching the vertical bridge die to conductive structures on the printed circuit board, the vertical bridge die and the at least one functional integrated circuit die being stacked between the semiconductor substrate and the printed circuit board,
wherein a back side of the at least one functional integrated circuit die and a front side of a first integrated circuit die of the semiconductor substrate face the printed circuit board.

18. The method as recited in claim 16 further comprising:
attaching additional vertical bridge die stacked with the semiconductor substrate, the first functional integrated circuit die being laterally disposed between the vertical bridge die and the additional vertical bridge die,
wherein the vertical bridge die, the first functional integrated circuit die, and the additional vertical bridge die are disposed in corresponding tiles of an N-by-M tile map of a surface of the semiconductor substrate and the vertical bridge die is separated from the first functional integrated circuit die by a lane having a predetermined width, wherein N and M are integers of at least one.

19. The method as recited in claim 15 further comprising:
vertically attaching a jumper die to a first integrated circuit die of the semiconductor substrate and a second integrated circuit die of the semiconductor substrate,
wherein the first integrated circuit die is separated from the second integrated circuit die by a scribe line of a first surface of the semiconductor substrate, wherein the jumper die spans the scribe line, overlaps a first portion of the first integrated circuit die, and overlaps a second portion of the second integrated circuit die.

20. The integrated circuit product formed by the method as recited in claim 15.
